(19) United States
(12) Patent Application Publication
(10) Pub. No.: US 2026/0116255 A1
(43) Pub. Date: Apr. 30, 2026

(54) AUTOMATED BATTERY ISOLATION TESTING SYSTEM WITH DUAL-CHANNEL MULTIMETER INTEGRATION FOR ELECTRIFIED VEHICLES

(71) Applicant: FCA US LLC, Auburn Hills, MI (US)

(72) Inventors: Gaurav Kumar, Auburn Hills, MI (US); Jianchao Zhu, Auburn Hills, MI (US)

(21) Appl. No.: 18/929,921

(22) Filed: Oct. 29, 2024

(51) Int. Cl. B60L 58/16; B60L 3/00; G01R 31/36; G01R 31/378; G01R 31/385; G01R 31/392

(52) U.S. Cl. CPC B60L 58/16; B60L 3/0046; G01R 31/3646; G01R 31/378; G01R 31/385; G01R 31/392

(57) ABSTRACT

An automated battery isolation testing (ABIT) system for a high voltage battery system of an electrified vehicle includes a dual-channel digital multimeter (DMM) and a control unit configured to, using first and second channels of the dual-channel DMM, measure first and second voltages between negative and positive terminals of the high voltage battery system and a chassis ground of the electrified vehicle, respectively, and based on a comparison therebetween, inserting a resistor having a known resistance between one of the negative and positive terminals and the chassis ground and obtain an updated first or second voltage and thereafter calculating an isolation resistance of the high voltage battery system and selectively generating a malfunction alert based on a comparison between the calculated isolation resistance and an isolation resistance threshold.

### FIELD

The present application generally relates to electrified vehicles and, more particularly, to an automated battery isolation testing (ABIT) system and method for electrified vehicle high voltage battery systems.

### BACKGROUND

Some electrified vehicles include a high voltage battery pack or system that is configured to power one or more electric traction motors for propulsion. Isolation resistance and insulation resistance are two different aspects of battery system testing. Insulation resistance is more commonly known and it represents the effectiveness of the insulating properties of the battery system components (connectors, wiring, etc.) and whether there is current leakage.

Isolation resistance, on the other hand, represents whether there is an unwanted path of current from the battery system terminals to the chassis ground (i.e., whether the battery system is electrically isolated) to avoid shock hazards or excessive discharging. The conventional two-meter method for isolating testing involves a skilled human technician manually measuring and calculating/logging the isolation resistance, which is time consuming and is prone to human error. Accordingly, while such conventional isolation testing techniques do work for their intended purpose, there exists an opportunity for improvement in the relevant art.

### SUMMARY

According to one example aspect of the invention, an automated battery isolation testing (ABIT) system for a high voltage battery system of an electrified vehicle is presented. In one exemplary implementation, the ABIT system comprises a dual-channel digital multimeter (DMM) configured to measure voltages using separate first and second channels and a control unit configured to measure, using the first channel of the dual-channel DMM, a first voltage between a negative terminal of the high voltage battery system and a chassis ground of the electrified vehicle, measure, using the second channel of the dual-channel DMM, a second voltage between a positive terminal of the high voltage battery system and the chassis ground, based on a comparison between the measured first and second voltages, insert a resistor having a known resistance between (i) one of the negative and positive terminals and (ii) the chassis ground and obtain an updated first or second voltage, based on the measured first and second voltages, the known resistance, and the updated first or second voltage, calculate an isolation resistance of the high voltage battery system, and selectively generate a malfunction alert based on a comparison between the calculated isolation resistance and an isolation resistance threshold.

In some implementations, the control unit is further configured to, when the measured first voltage is greater than or equal to the measured second voltage: insert the resistor between the negative terminal and the chassis ground and, after inserting the resistor, measure the first voltage to obtain the updated first voltage. In some implementations, the control unit is further configured to calculate the isolation resistance (Ri) as:

$$R i = R 0 \times U b ( \frac{1}{U {1}^{′}} - \frac{1}{U 1} ) ,$$

where R0 is the known resistance, U1 is the measured first voltage, U1′ is the updated first voltage, and Ub is a voltage across the positive and negative terminals.

In some implementations, the control unit is further configured to, when the measured first voltage is less than the measured second voltage: insert the resistor between the positive terminal and the chassis ground and. after inserting the resistor, measure the second voltage to obtain the updated second voltage. In some implementations, the control unit is further configured to calculate the isolation resistance (Ri) as:

$$R i = R 0 \times U b ( \frac{1}{U {2}^{′}} - \frac{1}{U 2} ) ,$$

where R0 is the known resistance, U2 is the measured second voltage, U2′ is the updated first voltage, and Ub is a voltage across the positive and negative terminals.

In some implementations, the control unit is further configured to generate the malfunction alert when the calculated isolation resistance is less than the isolation resistance threshold. In some implementations, the isolation resistance threshold is approximately 500 ohms per volt. In some implementations, the control unit is further configured to communicate via a controller area network (CAN) of the electrified vehicle.

In some implementations, the control unit is further configured to send, via the CAN, a wake-up request to a battery management system (BMS) of a control system of the electrified vehicle, wherein receipt of the wake-up command causes the BMS to wake-up the high voltage battery system. In some implementations, the control unit is further configured to maintain, via the CAN and the BMS, a desired state of the high voltage battery system, wherein the desired state indicates a state of a set of contactors of the high voltage battery system.

According to another aspect of the invention, an ABIT method for a high voltage battery system of an electrified vehicle is presented. In one exemplary implementation, the ABIT method comprises measuring, by a control unit and using a first channel of a dual-channel DMM, a first voltage between a negative terminal of the high voltage battery system and a chassis ground of the electrified vehicle, measuring, by the control unit and using a separate second channel of the dual-channel DMM, a second voltage between a positive terminal of the high voltage battery system and the chassis ground, based on a comparison between the measured first and second voltages, inserting, by the control unit, a resistor having a known resistance between (i) one of the negative and positive terminals and (ii) the chassis ground and obtain an updated first or second voltage, based on the measured first and second voltages, the known resistance, and the updated first or second voltage, calculating, by the control unit, an isolation resistance of the high voltage battery system, and selectively generating, by the control unit, a malfunction alert based on a comparison between the calculated isolation resistance and an isolation resistance threshold.

In some implementations, the ABIT method further comprises when the measured first voltage is greater than or equal to the measured second voltage: inserting, by the control unit, the resistor between the negative terminal and the chassis ground and, after inserting the resistor, measuring, by the control unit and using the first channel of the dual-channel DMM, the first voltage to obtain the updated first voltage. In some implementations, the ABIT method further comprises calculating the isolation resistance (Ri) as:

$$R i = R 0 \times U b ( \frac{1}{U {1}^{′}} - \frac{1}{U 1} ) ,$$

where R0 is the known resistance, U1 is the measured first voltage, U1′ is the updated first voltage, and Ub is a voltage across the positive and negative terminals.

In some implementations, the ABIT method further comprises when the measured first voltage is less than the measured second voltage: inserting, by the control unit, the resistor between the positive terminal and the chassis ground and, after inserting the resistor, measuring, by the control unit and using the second channel of the dual-channel DMM, the second voltage to obtain the updated second voltage. In some implementations, the ABIT method further comprises calculating, by the control unit, the isolation resistance (Ri) as:

$$R i = R 0 \times U b ( \frac{1}{U {2}^{′}} - \frac{1}{U 2} ) ,$$

where R0 is the known resistance, U2 is the measured second voltage, U2′ is the updated first voltage, and Ub is a voltage across the positive and negative terminals.

In some implementations, the ABIT method further comprises generating, by the control unit, the malfunction alert when the calculated isolation resistance is less than the isolation resistance threshold. In some implementations, the isolation resistance threshold is approximately 500 ohms per volt. In some implementations, the ABIT method further comprises communicating, by the control unit, via a CAN of the electrified vehicle.

In some implementations, the ABIT method further comprises sending, by the control unit and via the CAN, a wake-up request to BMS of a control system of the electrified vehicle, wherein receipt of the wake-up command causes the BMS to wake-up the high voltage battery system. In some implementations, the ABIT method further comprises maintaining, by the control unit and via the CAN and the BMS, a desired state of the high voltage battery system, wherein the desired state indicates a state of a set of contactors of the high voltage battery system.

Further areas of applicability of the teachings of the present application will become apparent from the detailed description, claims and the drawings provided hereinafter, wherein like reference numerals refer to like features throughout the several views of the drawings. It should be understood that the detailed description, including disclosed embodiments and drawings referenced therein, are merely exemplary in nature intended for purposes of illustration only and are not intended to limit the scope of the present disclosure, its application or uses. Thus, variations that do not depart from the gist of the present application are intended to be within the scope of the present application.

### BRIEF DESCRIPTION OF THE DRAWINGS

FIG. 1 is a functional block diagram of an electrified vehicle having a high voltage battery system and an example automated battery isolation testing (ABIT) system according to the principles of the present application;

FIGS. 2A-2C are circuit diagrams of example voltage measurements performed by the ABIT system according to the principles of the present application; and

FIG. 3 is a flow diagram of an example ABIT method for a high voltage battery system of an electrified vehicle according to the principles of the present application.

### DESCRIPTION

As previously discussed, isolation resistance represents whether there is an unwanted path of current from an electrified vehicle high voltage battery system's terminals to a chassis ground (i.e., whether the battery system is electrically isolated) to avoid shock hazards or excessive discharging. The conventional two-meter method for isolating testing involves a skilled human technician manually measuring and calculating/logging the isolation resistance, which is time consuming and is prone to human error. Accordingly, an automated battery isolation testing (ABIT) system and method that automates the process of isolation resistance testing of an electrified vehicle's high voltage battery system. The ABIT techniques integrate a dual-channel digital multimeter (DMM) to measure voltage across the battery system terminals and a control unit to handle the testing procedure, calculations, and logging. The ABIT techniques support controller area network (CAN) communication for initiating battery system wake-up and state/sequence maintaining and is also compatible with battery systems from different manufacturers or suppliers. Potential benefits include decreased costs and more accurate isolation resistance testing.

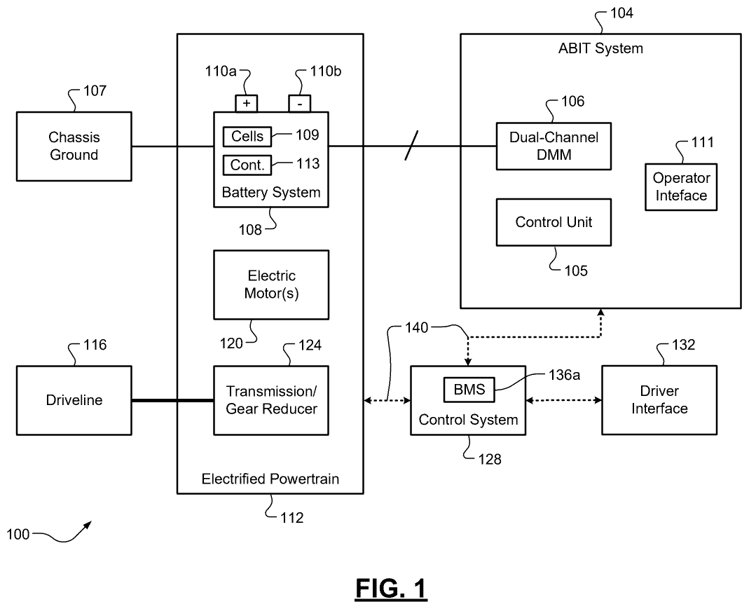

Referring now to FIG. 1, a functional block diagram of an electrified vehicle 100 including a high voltage battery pack or system 108 and an example ABIT system 104 according to the principles of the present application is illustrated. The electrified vehicle 100 includes an electrified powertrain 112 configured to generate and transfer drive torque to a driveline 116 for propulsion. The electrified powertrain 112 includes one or more electric motors 120 that are powered by electrical energy supplied by the high voltage battery system 108 and configured to generate the drive torque. The high voltage battery system 108 includes a plurality of battery cells 109 (e.g., lithium-ion type battery cells) connected in a suitable manner (e.g., in series) and positive and negative battery system terminals 110a, 110b (collectively, “terminals 110”). The drive torque from the electric motor(s) 120 could be directly provided to the driveline 116 or could be provided to the driveline via an intermediary transmission or gear reducer 124. In some implementations, the electrified powertrain 112 could further include a secondary power source, such as an internal combustion engine or a fuel cell (e.g., hydrogen fuel cell) system.

A control system 128 is configured to control operation of the electrified vehicle 100, which primarily involves controlling the electrified powertrain 112 to generate a desired amount of drive torque to satisfy a driver torque request received via a driver interface 132 (e.g., an accelerator pedal). In one exemplary implementation, the control system 128 includes a plurality of electronic control units (ECUs) 136 (e.g., a battery management system, or BMS 136a) configured to perform these various functions and to communicate with each other via a CAN 140. In some implementations, the control system 128 could be configured to perform at least a portion of the ABIT techniques of the present application, but it will also be appreciated that the ABIT system 104 could include its own controller or control unit 105 (e.g., a microcontroller) as shown. The ABIT system 104 generally comprises a dual-channel DMM 106 that is configured to measure both (i) a voltage of the positive terminal 110a of the high voltage battery system 108 relative to a chassis ground 107 and (ii) a voltage of the negative terminal 110b of the high voltage battery system 108 relative to the chassis ground 107.

The control unit 105 of the ABIT system 104 is configured to automate the isolation testing process, including performing various calculations as described more fully below and managing the flow of data to eliminate human error. The control unit 105 can also perform real-time data logging, e.g., continuously logging test results for future analysis and predictive maintenance. The control unit 105 is also configured for communication via the CAN 140, such as to execute wake-up and state/sequence maintaining of the high voltage battery system 108 (e.g., via communication with the BMS 136a) and to ensure seamless integration with a variety of battery pack/system configurations from different manufacturers or suppliers. Further, the control unit 105 can also detect and alert operators if the isolation resistance drops below a critical safety threshold (e.g., 500 ohms per volt). To briefly summarize, the ABIT system 104 is designed to automate the entire isolation resistance testing process, transforming it into a plug-and-play solution for electrified vehicle maintenance and safety assurance. The system 104 integrates a dual-channel DMM 106 that connects to the positive and negative terminals 110a, 110b of the high voltage battery system 108.

In operation, a first channel of the dual-channel DMM 106 (DMM 1) connects the positive terminal 110a to the chassis ground 107, while a second channel of the dual-channel DMM 106 (DMM 2) connects the negative terminal 110b to the chassis ground 107. This configuration ensures that the battery system 108 is properly isolated. If the battery system 108 is balanced, both channels of the dual-channel DMM 106 will show voltages, e.g., approximately half the total pack voltage (e.g., 400V for an 800V rated configuration of the high voltage battery system 108). The control unit 105 automates the test sequence by inserting a known resistor (R0) into the circuit, measuring the voltage drop, and calculating the isolation resistance in real-time. If the isolation resistance is below a specific isolation resistance threshold (e.g., 500 ohms per volt), the ABIT system 104 automatically generates an alert. As mentioned above, the system 104 incorporates CAN (e.g., CAN flexible data rate, or CAN-FD) communication for wake-up and state/sequence maintaining with the BMS 136a for the high voltage battery system 108. The ABIT system 104 incorporates CAN communication to facilitate seamless integration with the BMS 136a to allows the system 104 to the above-described functions.

A first function (1) is the wake-up control of the battery system 108. More specifically, the ABIT system 104 sends commands over the CAN 140 to wake-up the battery system 108 from a sleep state/mode, which is particularly useful for battery systems that are not fully operational during testing and require a wake-up signal to activate the internal circuitry). A second function (2) is state/sequence maintaining or, rather, maintaining a sequence of states with the BMS 136a. More specifically, during testing, the ABIT system 104 maintains continuous communication with the BMS 136a, ensuring that the battery system 108 remains in the correct operational state for accurate isolation resistance testing). The BMS 136a can also provide feedback and monitor the system status throughout the testing process, enhancing accuracy and safety. This feature ensures compatibility with a wide range of battery packs/systems from different manufacturers, making the ABIT system 104 versatile and adaptable to various electrified vehicle platforms. The inclusion of CAN/CAN FD communication protocols ensures that the system can interface with a wide variety of BMS implementations, making it a universal solution for electric vehicle testing.

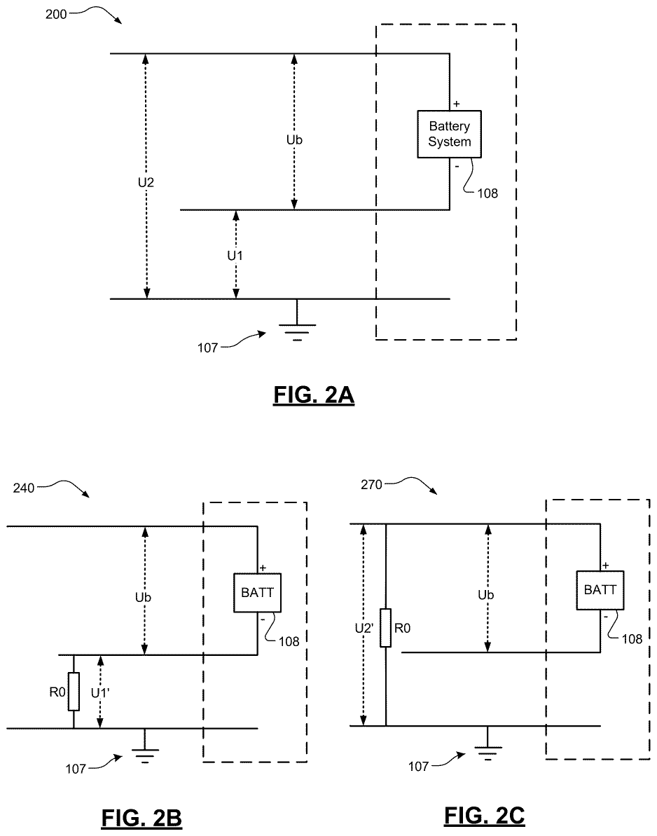

Referring now to FIGS. 2A-2C and with continued reference to FIG. 1, circuit diagrams 200, 240, 270 of various voltage measurements performed during the ABIT procedure according to the principles of the present application are illustrated. Before starting the testing sequence, the ABIT system 104 first wakes up the battery pack by sending a command over the CAN 140 to the BMS 136a for the battery system 108. The ABIT system 104, for example, could further provide an operator interface 111 (e.g., a liquid crystal display, or LCD touchscreen) where an operator (e.g., a technician) can issue the wake-up command, ensuring the battery system 108 is ready for testing. Once the battery system 108 is awake, the ABIT system 104 activates contactors (Cont.) 113 of the battery system 108 through the BMS 136a using the same interface 111. This step ensures that the high voltage circuits are closed, and the terminals 110 are fully operational before the isolation resistance testing begins.

After the battery system 108 is awake and the contactors 113 are closed, the ABIT 104 system measures and compares the voltage between the positive terminal 110a and ground (voltage U1) and the negative terminal 110b and ground (voltage U2) as shown in FIG. 2A. The ABIT system 104 then determines whether voltage U1 is greater than or equal to voltage U2. When true (i.e., when U1≥U2), a known resistor (R0) is inserted between the negative terminal 110b and the chassis ground 107 as shown in FIG. 2B. The ABIT system 104 then powers on the battery system 108 and records the updated voltage (U1′) as measured by the first channel of the dual-channel DMM 106 and then powers off the battery system 108. When false (i.e., when U2≥U1), the ABIT system 104 inserts the known resistor R0 between the positive terminal 110a and the chassis ground 107 as shown in FIG. 2C. The ABIT system 104 then powers on the battery system 108 and records the updated voltage (U2′) as measured by the second channel of the dual-channel DMM 106 and then powers off the battery system 108. The ABIT system 104 then automatically processes the recorded voltage values (U1, U2, U1′, U2′) and the known resistance (R0).

The isolation resistance (Ri) is calculated using one of the following formulas, depending on the terminal 110 tested:

$$R i = R 0 \times U b ( \frac{1}{U {1}^{′}} - \frac{1}{U 1} ) , or \qquad ( 1 )$$

$$Ri = R 0 \times U b ( \frac{1}{U {2}^{′}} - \frac{1}{U 2} ) , \qquad ( 2 )$$

where Ub is the voltage between the terminals 110. The system compares the calculated isolation resistance Ri to a specific threshold (e.g., a required isolation threshold of 500 Ω/V). If the calculated isolation resistance Ri is below the threshold, the ABIT system 104 generates a malfunction or fail alert and transmits the results to an external system for further analysis via the CAN 140. For example, this external system could be a computing system located at a service station for the electrified vehicle 100. As mentioned above, additional features include real-time data logging, which allows operators to monitor battery health and diagnose potential isolation issues.

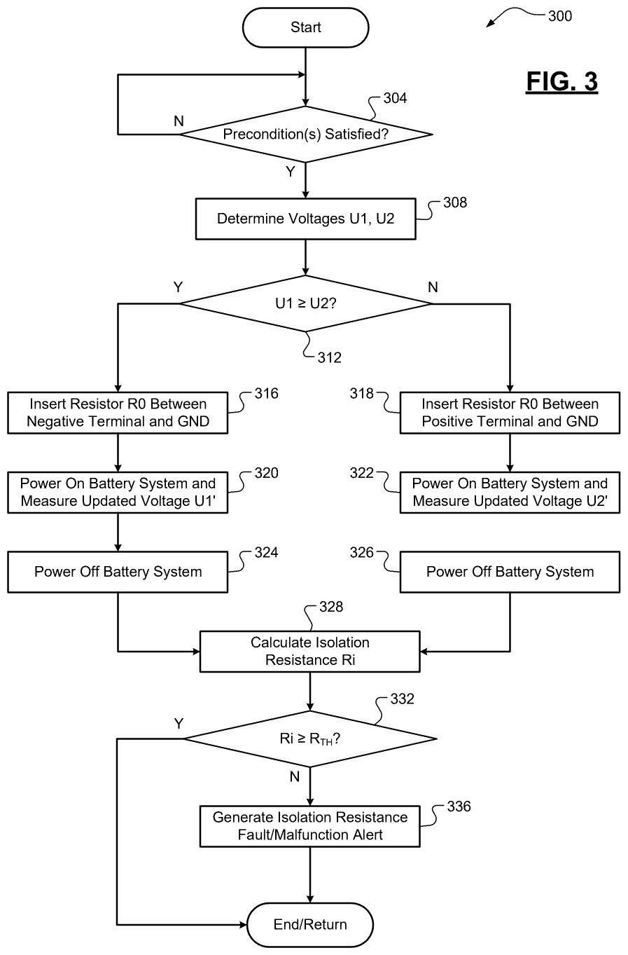

Referring now to FIG. 3 and with continued reference to the previous figures, a flow diagram of an example ABIT method 300 for a high voltage battery system of an electrified vehicle according to the principles of the present application is illustrated. While the method 300 specifically references the electrified vehicle 100 and the ABIT system 104 and their sub-components, it will be appreciated that the method 300 could be applicable to any suitably configured electrified vehicle 100 as well as other alternative configurations of the ABIT system 104. The method 300 begins at 304 where the ABIT system 104 (i.e., the control unit 105) determines whether a set of preconditions are satisfied. These precondition(s) could include, for example only, the battery system 108 having been woken up (via communication with the BMS 136a via the CAN 140) and contactors 113 associated with the battery system 108 being closed such that the battery system 108 is not electrically isolated. The precondition(s) could further include there being no other faults or malfunctions present that would negatively impact or otherwise inhibit the operation of the ABIT techniques of the present application (e.g., a contactor malfunction of the battery system 108, such as one of the contactor(s) 113 being welded or stuck). When the precondition(s) are satisfied, the method 300 proceeds to 308. Otherwise, the method 300 ends or returns to 304.

At 308, the ABIT system 104 determines voltages U1 and U2 as shown in FIG. 2A. At 312, the ABIT system 104 compares voltages U1 and U2. When U1 is greater than or equal to U2, the method 300 proceeds to 316. Otherwise (i.e., when U2>U1), the method 300 proceeds to 318. At 316, the ABIT system 104 inserts the known resistor R0 between the negative terminal 110b and the chassis ground 107. At 320, the ABIT system 204 powers on the battery system 108 and measures the updated voltage U1′ using the first channel of the dual-channel DMM 106. At 324, the ABIT system 104 powers off the battery system 108. At 318, the ABIT system 104 inserts the known resistor R0 between the positive terminal 110a and the chassis ground 107. At 322, the ABIT system 104 powers on the battery system 108 and measures the updated voltage U2′ using the second channel of the dual-channel DMM 106. At 326, the ABIT system 104 powers off the battery system 108. At 328, the ABIT system 104 calculates the isolation resistance Ri using one of the above-described formulas (depending on the terminal 110 tested). At 332, the ABIT system 104 compares the calculated isolation resistance Ri to the isolation resistance threshold (R_{TH}), such as 500 ohms per volt. When the calculated isolation resistance Ri is greater than or equal to the isolation resistance threshold R_{TH}, the method 300 ends (the test passes). When the calculated isolation resistance Ri is less than the isolation resistance threshold R_{TH}, the method 300 proceeds to 336 where the ABIT system 104 generates a fault or malfunction alert, which could be transmitted via the CAN 140 and then used to alert an operator and/or for further analysis.

It will be appreciated that the terms “controller” and “control system” as used herein refer to any suitable control device or set of multiple control devices that is/are configured to perform at least a portion of the techniques of the present application. Non-limiting examples include an application-specific integrated circuit (ASIC), one or more processors and a non-transitory memory having instructions stored thereon that, when executed by the one or more processors, cause the controller to perform a set of operations corresponding to at least a portion of the techniques of the present application. The one or more processors could be either a single processor or two or more processors operating in a parallel or distributed architecture.

It should also be understood that the mixing and matching of features, elements, methodologies and/or functions between various examples may be expressly contemplated herein so that one skilled in the art would appreciate from the present teachings that features, elements and/or functions of one example may be incorporated into another example as appropriate, unless described otherwise above.

What is claimed is:

1. An automated battery isolation testing (ABIT) system for a high voltage battery system of an electrified vehicle, the ABIT system comprising:
a dual-channel digital multimeter (DMM) configured to measure voltages using separate first and second channels; and
a control unit configured to:
measure, using the first channel of the dual-channel DMM, a first voltage between a negative terminal of the high voltage battery system and a chassis ground of the electrified vehicle;
measure, using the second channel of the dual-channel DMM, a second voltage between a positive terminal of the high voltage battery system and the chassis ground;
based on a comparison between the measured first and second voltages, insert a resistor having a known resistance between (i) one of the negative and positive terminals and (ii) the chassis ground and obtain an updated first or second voltage;
based on the measured first and second voltages, the known resistance, and the updated first or second voltage, calculate an isolation resistance of the high voltage battery system; and
selectively generate a malfunction alert based on a comparison between the calculated isolation resistance and an isolation resistance threshold.

2. The ABIT system of claim 1, wherein the control unit is further configured to, when the measured first voltage is greater than or equal to the measured second voltage:
insert the resistor between the negative terminal and the chassis ground; and
after inserting the resistor, measure the first voltage to obtain the updated first voltage.

3. The ABIT system of claim 2, wherein the control unit is further configured to calculate the isolation resistance (Ri) as:
$$R i = R 0 \times U b ( \frac{1}{U {1}^{′}} - \frac{1}{U 1} ) ,$$
where R0 is the known resistance, U1 is the measured first voltage, U1′ is the updated first voltage, and Ub is a voltage across the positive and negative terminals.

4. The ABIT system of claim 1, wherein the control unit is further configured to, when the measured first voltage is less than the measured second voltage:
insert the resistor between the positive terminal and the chassis ground; and
after inserting the resistor, measure the second voltage to obtain the updated second voltage.

5. The ABIT system of claim 4, wherein the control unit is further configured to calculate the isolation resistance (Ri) as:
$$R i = R 0 \times U b ( \frac{1}{U {2}^{′}} - \frac{1}{U 2} )$$
where R0 is the known resistance, U2 is the measured second voltage, U2′ is the updated first voltage, and Ub is a voltage across the positive and negative terminals.

6. The ABIT system of claim 1, wherein the control unit is further configured to generate the malfunction alert when the calculated isolation resistance is less than the isolation resistance threshold.

7. The ABIT system of claim 6, wherein the isolation resistance threshold is approximately 500 ohms per volt.

8. The ABIT system of claim 1, wherein the control unit is further configured to communicate via a controller area network (CAN) of the electrified vehicle.

9. The ABIT system of claim 8, wherein the control unit is further configured to send, via the CAN, a wake-up request to a battery management system (BMS) of a control system of the electrified vehicle, wherein receipt of the wake-up command causes the BMS to wake-up the high voltage battery system.

10. The ABIT system of claim 9, wherein the control unit is further configured to maintain, via the CAN and the BMS, a desired state of the high voltage battery system, wherein the desired state indicates a state of a set of contactors of the high voltage battery system.

11. An automated battery isolation testing (ABIT) method for a high voltage battery system of an electrified vehicle, the ABIT method comprising:
measuring, by a control unit and using a first channel of a dual-channel digital multimeter (DMM), a first voltage between a negative terminal of the high voltage battery system and a chassis ground of the electrified vehicle;
measuring, by the control unit and using a separate second channel of the dual-channel DMM, a second voltage between a positive terminal of the high voltage battery system and the chassis ground;
based on a comparison between the measured first and second voltages, inserting, by the control unit, a resistor having a known resistance between (i) one of the negative and positive terminals and (ii) the chassis ground and obtain an updated first or second voltage;
based on the measured first and second voltages, the known resistance, and the updated first or second voltage, calculating, by the control unit, an isolation resistance of the high voltage battery system; and
selectively generating, by the control unit, a malfunction alert based on a comparison between the calculated isolation resistance and an isolation resistance threshold.

12. The ABIT method of claim 11, further comprising when the measured first voltage is greater than or equal to the measured second voltage:
inserting, by the control unit, the resistor between the negative terminal and the chassis ground; and
after inserting the resistor, measuring, by the control unit and using the first channel of the dual-channel DMM, the first voltage to obtain the updated first voltage.

13. The ABIT method of claim 12, further comprising calculating the isolation resistance (Ri) as:
$$R i = R 0 \times U b ( \frac{1}{U {1}^{′}} - \frac{1}{U 1} ) ,$$
where R0 is the known resistance, U1 is the measured first voltage, U1′ is the updated first voltage, and Ub is a voltage across the positive and negative terminals.

14. The ABIT method of claim 11, further comprising when the measured first voltage is less than the measured second voltage:
inserting, by the control unit, the resistor between the positive terminal and the chassis ground; and
after inserting the resistor, measuring, by the control unit and using the second channel of the dual-channel DMM, the second voltage to obtain the updated second voltage.

15. The ABIT method of claim 14, further comprising calculating, by the control unit, the isolation resistance (Ri) as:
$$R i = R 0 \times U b ( \frac{1}{U {2}^{′}} - \frac{1}{U 2} ) ,$$
where R0 is the known resistance, U2 is the measured second voltage, U2′ is the updated first voltage, and Ub is a voltage across the positive and negative terminals.

16. The ABIT method of claim 11, further comprising generating, by the control unit, the malfunction alert when the calculated isolation resistance is less than the isolation resistance threshold.

17. The ABIT method of claim 16, wherein the isolation resistance threshold is approximately 500 ohms per volt.

18. The ABIT method of claim 11, further comprising communicating, by the control unit, via a controller area network (CAN) of the electrified vehicle.

19. The ABIT method of claim 18, further comprising sending, by the control unit and via the CAN, a wake-up request to a battery management system (BMS) of a control system of the electrified vehicle, wherein receipt of the wake-up command causes the BMS to wake-up the high voltage battery system.

20. The ABIT method of claim 19, further comprising maintaining, by the control unit and via the CAN and the BMS, a desired state of the high voltage battery system, wherein the desired state indicates a state of a set of contactors of the high voltage battery system.
